(19) United States
(12) Patent Application Publication
(10) Pub. No.: US 2021/0111859 A1
(43) Pub. Date: Apr. 15, 2021

(54) CLOCK DATA RECOVERY CIRCUIT WITH IMPROVED PHASE INTERPOLATION

(71) Applicant: QUALCOMM Incorporated, San Diego, CA (US)

(72) Inventor: Dayasagar Reddy GAADE, Bangalore (IN)

(21) Appl. No.: 16/598,213

(22) Filed: Oct. 10, 2019

(51) Int. Cl. H04L 7/00; H03L 7/081; H03L 7/089; H03L 7/099; H03L 7/08; H04L 7/033

(52) U.S. Cl. CPC H04L 7/0025; H03L 7/0812; H04L 7/0331; H03L 7/0998; H03L 7/0807; H03L 7/0891

(57) ABSTRACT

A clock data recovery circuit includes a ring oscillator that generates a plurality of ring oscillator clock signal responsive to an input clock signal. A delay-locked loop delays a selected one of the ring oscillator clock signals to generate a plurality of delay-locked loop clock signals. A data sampler selects from the plurality of delay-locked loop clock signals to sample a received data stream.

### TECHNICAL FIELD

This application relates to clock data recovery circuits, and more particularly to a clock data recovery circuit with improved phase interpolation.

### BACKGROUND

High-speed transmission of multi-bit words is limited by the skew between the individual bits transmitted in parallel. To address such skew, various serializer/deserializer (SerDes) systems have been developed. A SerDes transmitter serializes a multi-bit word into a series of corresponding bits for transmission to a receiver. A SerDes receiver deserializes the received serial bit stream into the original word. SerDes systems may be either source synchronous or use an embedded clock. Both source synchronous and embedded clock systems include a clock data recovery (CDR) circuit to align the received (or recovered) clock signal with the data eye for the received serial data stream.

### SUMMARY

In accordance with a first aspect of the disclosure, a clock data recovery circuit is provided that includes: a ring oscillator configured to generate a plurality of ring oscillator clock signals responsive to an input clock signal; a delay-locked loop (DLL) configured to delay a selected ring oscillator clock signal from the plurality of ring oscillator clock signals to generate a plurality of DLL clock signals; and a data sampler configured to sample a received data stream with a selected DLL clock signal from the plurality of DLL clock signals to generate a sampled data stream.

In accordance with a second aspect of the disclosure, a method of clock data recovery is provided that includes: generating a plurality of ring oscillator clock signals in a ring oscillator; selecting from the plurality of ring oscillator clock signals to provide a selected ring oscillator clock signal to a delay-locked loop (DLL); delaying the selected ring oscillator clock signal through the DLL to generate a plurality of DLL clock signals; selecting from the plurality of DLL clock signals to provide a selected DLL clock signal; and sampling a received data stream with a selected DLL clock signal.

In accordance with a third aspect of the disclosure, a clock data recovery circuit is provided that includes: a ring oscillator configured to generate a plurality of ring oscillator clock signals responsive to an input clock signal; means for synchronizing the plurality of ring oscillator clock signals with the input clock signal; a delay-locked loop (DLL) configured to delay a selected ring oscillator clock signal from the plurality of ring oscillator clock signals to generate a plurality of DLL clock signals; and a data sampler configured to sample a received data stream with the selected DLL clock signal from the plurality of DLL clock signals to generate a sampled data stream.

In accordance with a fourth aspect of the disclosure, a clock data recovery circuit is provided that includes: a ring oscillator; a first clock multiplexer for selecting from a plurality of ring oscillator clock signals from the ring oscillator to provide a selected ring oscillator clock signal; a delay-locked loop (DLL); a second clock multiplexer for selecting from a plurality of DLL clock signal from the DLL to provide a sampling clock signal; and a data sampler for sampling a received serial data stream with sampling clock signal to provide a series of data samples.

These and other advantageous features may be better appreciated through the following detailed description.

### BRIEF DESCRIPTION OF THE DRAWINGS

FIG. 1 is a diagram of an example ring oscillator in accordance with an aspect of the disclosure.

FIG. 2 is a diagram of an example delay-locked loop in accordance with an aspect of the disclosure.

FIG. 3 is a diagram of an example CDR circuit incorporating a ring oscillator and a DLL in accordance with an aspect of the disclosure.

FIG. 4 is a flowchart for an example method of operation for a CDR circuit in accordance with an aspect of the disclosure.

FIG. 5 illustrates some example electronic systems each incorporating a clock data recovery circuit in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

An improved phase-interpolator-based CDR circuit is disclosed that interpolates analogously to the interpolation in a Vernier scale. In the CDR circuit, it is the period of the recovered clock signal or received clock signal that is being divided. Whether the clock signal is recovered or received depends upon whether the SerDes receiver including the CDR circuit is source synchronous or uses an embedded clock. In an embedded clock system, the clock signal is recovered from a received serial data stream whereas it is a received clock signal in a source synchronous system. For brevity, the recovered or received clock signal is referred to herein as the input clock signal. The CDR circuit interpolates based upon the input clock signal to produce a sampling clock signal that is used to sample a received serial data stream.

The CDR circuit includes a ring oscillator having a plurality of N stages that are controlled to produce corresponding ring oscillator clock signals that are synchronous with the input clock signal, N being a plural positive integer. A period of the recovered clock signal is divided according to the number of stages in the ring oscillator. Each stage produces its own ring oscillator clock signal. For example, suppose that there are five stages in the ring oscillator. The period would then be divided into five phases, each phase separated by 360/5=72 degrees. More generally, the 360-degree period for the recovered clock signal is divided by 360/N degrees of phase for the N stages in the ring oscillator. A first ring oscillator clock signal is produced by a first one of the stages may then be delayed by 360/N degrees with respect to the input clock signal. Each successive stage is delayed by another 360/N degrees. A second ring oscillator clock signal produced by a second one of the stages is thus delayed by 2*360/N degrees with respect to the input clock signal, and so on for the remaining stages. It will be appreciated that the phase alignment for the various ring oscillator clock signals may be varied in alternative implementations. For example, the first ring oscillator clock signal may be delayed by 0 degrees with respect to the input clock signal. Regardless of the phase alignment of the first clock signal with the input clock signal, each successive ring oscillator clock signal is delayed by 360/N degrees with regard to the preceding ring oscillator clock signal. The ring oscillator clock signals may have a frequency that is a multiple of the input clock signal frequency.

Although the resulting CDR circuit is of course not a Vernier scale, the phase interpolation by the CDR circuit is “Vernier-like” in that the coarse increments of phase separating the ring oscillator clock signals are in turn divided into finer increments of phase by a delay-locked loop (DLL). Depending upon the phase interpolation to produce an interpolated clock signal that is centered or otherwise suitably aligned with the data eye for the received serial data stream, a first clock multiplexer selects from the ring oscillator clock signals to provide a DLL input clock signal to the DLL. The fine division of the coarse increments of phase by the DLL depends upon the number of delay elements within the DLL. In general, the DLL may include an arbitrary plurality of delay elements, but the following discussion will assume that the DLL includes (N−1) delay elements, where N is the number of stages in the ring oscillator. In such an implementation, the N equal coarse phase increments from the ring oscillator are divided into (N−1) equal parts by the DLL, which results in an advantageously fine phase interpolation.

Each delay element in the DLL produces a corresponding DLL output clock signal on a one-to-one basis such that for every delay element there is a corresponding DLL output clock signal. In an implementation with N−1 delay elements, there are thus N−1 DLL output clock signals. A data sampler discussed further herein selects from the DLL output clock signals to select a sampling clock signal that is suitably centered within the data eye for the received serial data stream so that the received serial data stream may be sampled by the sampling clock signal.

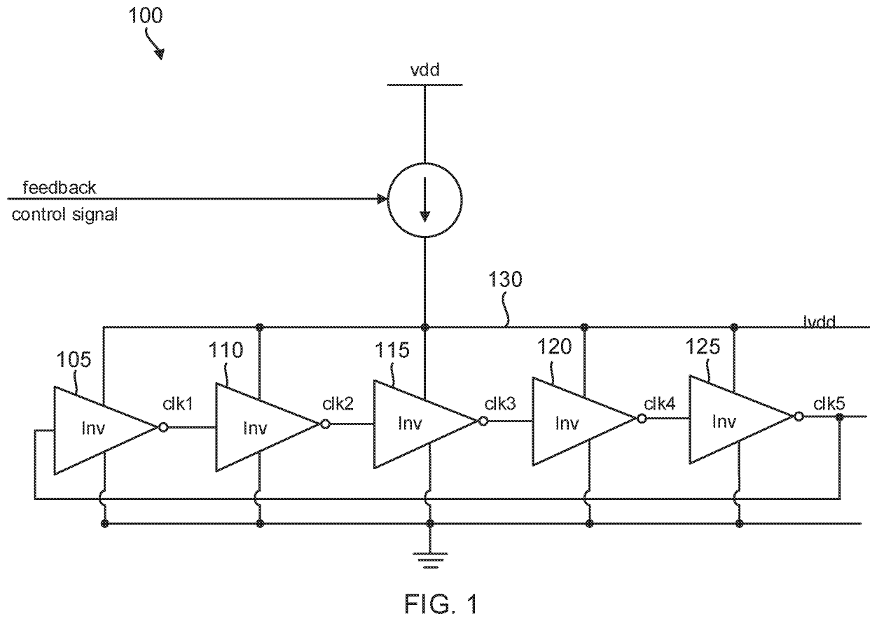

An example ring oscillator 100 is shown in FIG. 1. Each stage in ring oscillator 100 is formed by a corresponding inverter. Each inverter produces a corresponding ring oscillator clock signal. The number of inverters in ring oscillator 100 depends upon the desired precision for the resulting CDR circuit. In ring oscillator 100 there are five inverters, but it will be appreciated that alternative implementations may uses greater than or less than five inverters. As known in the ring oscillator arts, oscillation of a ring oscillator typically requires an odd number of inverters. The plurality of inverters in ring oscillator 100 produce a corresponding plurality of ring oscillator clock signals on a one-to-one basis. In ring oscillator 10, a first inverter 105 produces a first ring oscillator clock signal (clk1). Each successive inverter in ring oscillator 100 inverts the ring oscillator clock signal from the preceding inverter. For example, a second inverter 110 inverts the first ring oscillator signal to produce a second ring oscillator clock signal (clk2). A third inverter 115 inverts the second ring oscillator signal to produce a third ring oscillator clock signal (clk3). A fourth inverter 120 inverts the third ring oscillator clock signal to produce a fourth ring oscillator clock signal (clk4). Finally, a fifth inverter 125 inverts the fourth ring oscillator clock signal to form a fifth ring oscillator clock signal (clk5). To complete the loop, first inverter 105 inverts the fifth ring oscillator clock signal to form the first ring oscillator clock signal.

As will be explained further herein, ring oscillator 100 is contained within a phase-locked loop (PLL) that controls the ring oscillator clock signals to be synchronous with the input clock signal. Since ring oscillator 100 includes five inverters, the phase shift from one inverter to a successive inverter in ring oscillator is 360/5=72 degrees. The oscillation frequency for the various ring oscillator clock signals in ring oscillator 100 depends upon a power supply voltage lvdd carried on a local power rail 130 that powers each of the inverters. As will be explained further herein, a feedback loop (not illustrated in FIG. 1) in the PLL incorporating ring oscillator 100 controls a current source 140 that couples between local power rail 130 and a global power rail 140 carrying a global power supply voltage vdd. In some implementations, the feedback loop controls current source 140 so that the frequency of the ring oscillator clock signals equals the frequency of the input clock signal. More generally, the period for the ring oscillator clock signals is maintained by the feedback loop to have a fixed relationship to the period for the input clock signal.

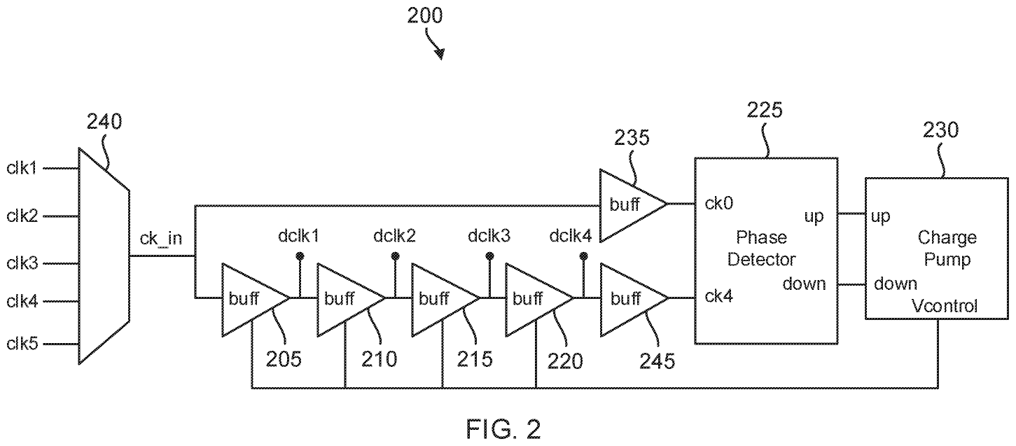

An example DLL 200 is shown in FIG. 2. A first clock multiplexer 240 selects between the ring oscillator clock signals. In an implementation in which the ring oscillator has five stages such as discussed for ring oscillator 100, first clock multiplexer 240 selects from the first through fifth ring oscillator clock signals: clk1, clk2, clk3, clk4, and clk5. The selected clock signal from first clock multiplexer 240 forms a DLL input clock signal ck_in for DLL 200.

DLL 200 has four delay stages formed by a first buffer 205, a second buffer 210, a third buffer 215, and a fourth buffer 220. These delay stages correspond to a plurality of four DLL clock signals on a one-to-one-basis. As defined herein, the terms “buffer” and “delay circuit” are used interchangeably. First buffer 205 delays the DLL input clock signal to form a first DLL clock signal dclk1. Second buffer 210 delays the first DLL clock signal to form a second DLL clock signal dclk2. Third buffer 215 delays the second DLL clock signal to form a third DLL clock signal dclk3. Finally, fourth buffer 220 delays the third DLL clock signal to form a fourth DLL clock signal dclk4. In the delay chain formed by the buffers, first buffer 205 may also be denoted as a beginning buffer whereas fourth buffer 220 may be denoted as a final buffer. DLL 200 uses feedback to maintain a quadrature relationship from one DLL clock signal to the succeeding DLL clock signal across the delay chain of buffers. To implement the feedback, a phase detector 225 compares a delayed version (ck4) of the fourth DLL clock signal as delayed through a buffer 245 to a delayed version (ck0) of the DLL input clock signal as delayed through a buffer 235. Based upon the detected phase difference between the ck0 and ck4 signals, phase detector 225 either asserts an up signal or a down signal to a charge pump 230 to either increase or decrease a control voltage Vcontrol accordingly. The control voltage controls the amount of delay applied by buffers 205, 210, 215, and 220 to maintain the desired quadrature relationship between the successive DLL clock signals. Thus, the second DLL clock signal is delayed by 90 degrees with respect to the first DLL clock signal. The third DLL clock signal is delayed by 180 degrees with respect to the first DLL clock signal. Finally, the fourth DLL clock signal is delayed by 270 degrees with respect to the first DLL clock signal. Phase detector 225 and charge pump 230 form a feedback loop for DLL 200.

The resulting phase interpolation depends upon which ring oscillator clock signal is chosen by first clock multiplexer 240 and upon which DLL clock signal is used to sample the received serial data stream. The following Table 1 lists the phase increments of the period T for the recovered clock signal for the various combinations of selected ring oscillator clock signal and the DLL clock signal used to sample the received serial data stream.

| Ring Oscillator | DLL Clock | Phase Shift |
|---|---|---|
| Clock Signal | Signal | in units of T |
| clk5 | dclk1 | 0 |
| clk4 | dclk2 | T/20 |
| clk3 | dclk3 | 2T/20 |
| clk2 | dclk4 | 3T/20 |
| clk1 | dclk1 | 4T/20 |
| clk5 | dclk2 | 5T/20 |
| clk4 | dclk3 | 6T/20 |
| clk3 | dclk4 | 7T/20 |
| clk2 | dclk1 | 8T/20 |
| clk1 | dclk2 | 9T/20 |
| clk5 | dclk3 | 10T/20 |
| clk4 | dclk4 | 11T/20 |
| clk3 | dclk1 | 12T/20 |
| clk2 | dclk2 | 13T/20 |
| clk1 | dclk3 | 14T/20 |
| clk5 | dclk4 | 15T/20 |
| clk4 | dclk1 | 16T/20 |
| clk3 | dclk2 | 17T/20 |
| clk2 | dclk3 | 18T/20 |
| clk1 | dclk4 | 19T/20 |

As can be seen from Table 1, the appropriate selection of the ring oscillator clock signal and the DLL clock signal leads to a phase interpolation across the entire period T in increments of T/20.

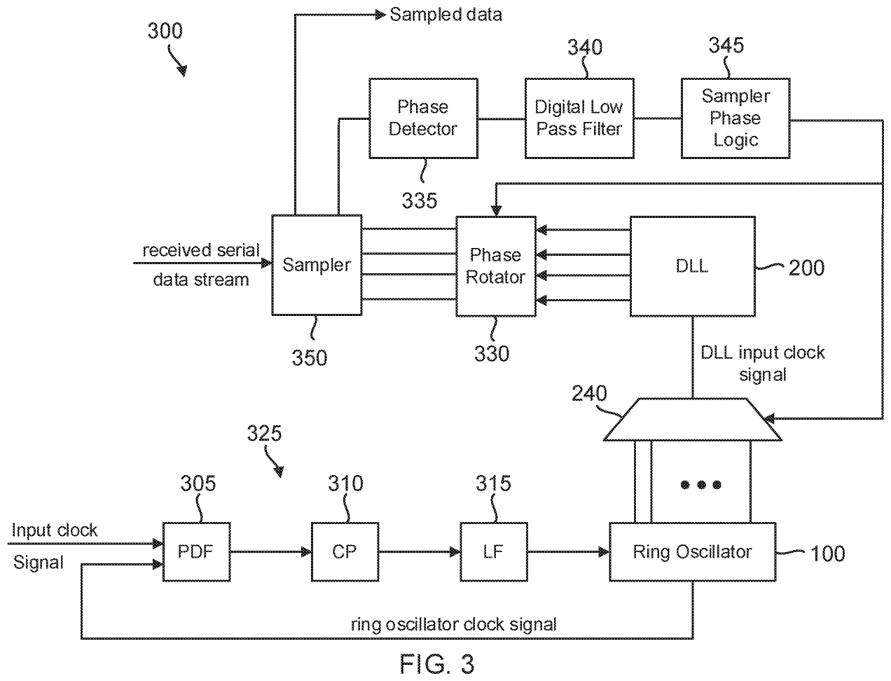

A CDR circuit 300 incorporating ring oscillator 100 and DLL 200 is shown in FIG. 3. Ring oscillator 100 is part of a phase-locked loop (PLL) 325 that keeps the ring oscillator clock signals from ring oscillator 100 synchronized with the input clock signal. In PLL 325, a selected one of the ring oscillator clock signals is compared to the input clock signal in a phase detector (PFD) 305. Depending upon the phase difference between the input clock signal and the selected ring oscillator clock signal as detected by phase detector 305, a charge pump (CP) 310 either charges or discharges a control voltage that is filtered by a loop filter (LF) 315 to produce the feedback control signal for PLL 325. The feedback control signal controls the frequency of oscillation for the ring oscillator clock signals as discussed for FIG. 1. It will be appreciated that PLL 325 may be implemented using digital circuits in alternative implementations. In one implementation. PLL 325 may be deemed to comprises a means for synchronizing the plurality of ring oscillator clock signals with the input clock signal.

First clock multiplexer 240 selects from the plurality of N ring oscillator clock signals to provide the DLL input clock signal to DLL 200. In CDR circuit 300, DLL 200 produces four quadrature DLL clock signals, but it will be appreciated that the number of DLL clock signal produced by DLL 200 depends upon the number of delay elements within DLL 200. A phase rotator 330 performs a clock selection from the quadrature DLL clock signals to obtain the desired phase interpolations. Phase rotator 330 may thus also be denoted as a second clock multiplexer to select a sampling clock signal from the quadrature DLL clock signals. A sampler 350 samples the received serial data stream using the selected sampling clock signal from phase rotator 330 to provide a sampled data stream. Sampler 350 also samples the receiver serial data stream with the quadrature of the sampling clock signal so that a digital phase detector 335 may detect a digital phase difference from sampler 350 that is filtered by a digital low pass filter 340 to provide a control signal to a sampler phase logic circuit 345. Sampler phase logic circuit 345 controls the quadrature DLL clock signal selection in phase rotator 330 and the selection by first clock multiplexer 240 so that the sampling by sampler 350 is maintained as desired with the data eye for the received serial data stream. Note that the fine phase resolution for the resulting phase interpolation is obtained using DLL 200 so that skew is reduced in the sampling the received serial data stream. Moreover, the resulting fine phase resolution results in a lower bit error rate for the sampled data stream. In addition, the combination of ring oscillator 100 and DLL 200 results in a relatively compact design with reduced power consumption.

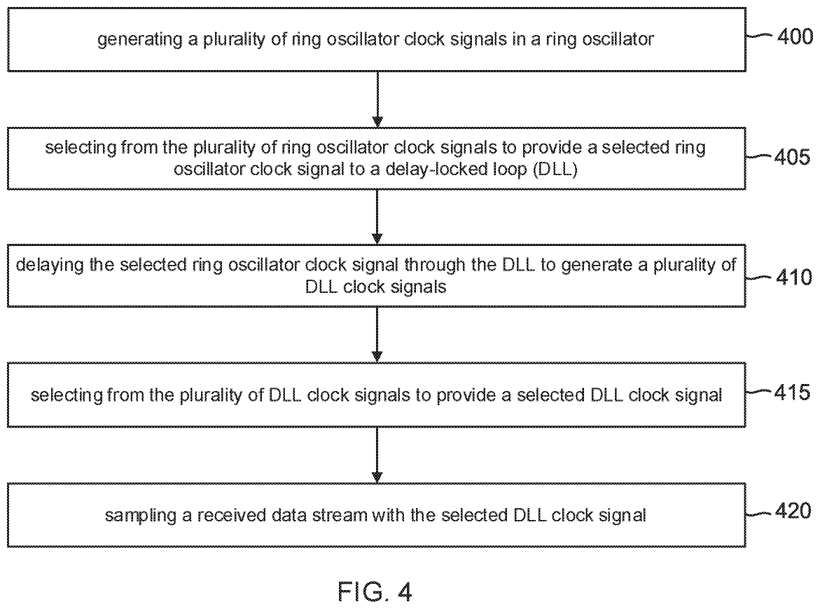

A method of operation for a CDR circuit as disclosed herein will now be discussed with reference to the flowchart of FIG. 4. The method includes an act 400 of generating a plurality of ring oscillator clock signals in a ring oscillator such as discussed for ring oscillator 100. The method also includes an act 405 of selecting from the plurality of ring oscillator clock signals to provide a selected ring oscillator clock signal to a delay-locked loop (DLL) such as performed by first clock multiplexer 240. In addition, the method includes an act 410 of delaying the selected ring oscillator clock signal through the DLL to generate a plurality of DLL clock signals such as practiced by DLL 200. The method also includes an act 415 of selecting from the plurality of DLL clock signals to provide a selected DLL clock signal such as practiced by phase rotator 330. Finally, the method includes an act 420 of sampling a received data stream with the selected DLL clock signal. The sampling by sampler 350 is an example of act 420.

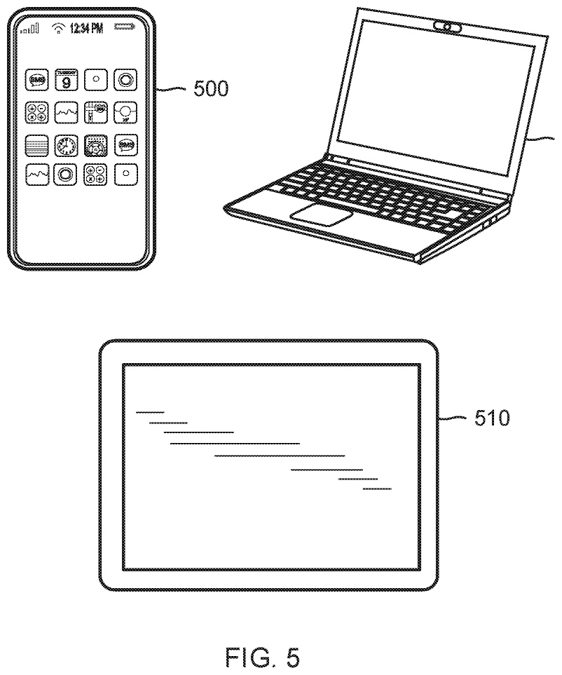

A clock data recovery circuit as disclosed herein may be advantageously incorporated in any suitable electronic system. For example, as shown in FIG. 5, a cellular device such as a cellular telephone 500, a laptop computer 505, and a tablet PC 510 may all include a clock data recovery circuit in accordance with the disclosure. Other exemplary electronic systems such as a music player, a video player, a communication device, and a personal computer may also be configured with clock data recovery circuits constructed in accordance with the disclosure.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

1. A clock data recovery circuit, comprising:
a phase-locked loop (PLL) including a ring oscillator configured to generate a plurality of ring oscillator clock signals responsive to an input clock signal, the ring oscillator including a plurality of inverters, the PLL being configured to control a power supply voltage for the plurality of inverters to synchronize the plurality of ring oscillator clock signals with the input clock signal;
a delay-locked loop (DLL) configured to delay a selected ring oscillator clock signal from the plurality of ring oscillator clock signals to generate a plurality of DLL clock signals; and
a data sampler configured to sample a received data stream with a selected DLL clock signal from the plurality of DLL clock signals to generate a sampled data stream.

2. (canceled)

3. The clock data recovery circuit of claim 1, wherein the PLL comprises:
a phase detector configured to detect a phase difference between a ring oscillator clock signal from the plurality of ring oscillator clock signals and the input clock signal;
a charge pump configured to drive a control voltage responsive to the phase difference; and
a loop filter configured to filter the control voltage to produce a feedback control signal.

4. The clock data recovery circuit of claim 3, wherein the PLL further comprises a current source configured to control the power supply voltage responsive to the feedback control signal.

5. The clock data recovery circuit of claim 1, further comprising:
a first clock multiplexer configured to select from the plurality of ring oscillator clock signals to provide the selected ring oscillator clock signal; and
a second clock multiplexer configured to select from the plurality of DLL clock signals to provide the selected DLL clock signal.

6. The clock data recovery circuit of claim 5, wherein the data sampler further comprises a feedback circuit configured to control the first clock multiplexer and to control the second clock multiplexer.

7. The clock data recovery circuit of claim 1, wherein the DLL comprises a plurality of buffers corresponding to the plurality of DLL clock signals on a one-to-one basis, wherein each buffer is configured to produce the corresponding DLL clock signal.

8. The clock data recovery circuit of claim 7, wherein the plurality of buffers is arranged in serial from a beginning buffer to a final buffer, and wherein the DLL further comprises:
a feedback loop configured to control a control voltage for the plurality of buffers to synchronize the corresponding DLL clock signal for the final buffer with the selected ring oscillator clock signal.

9. The clock data recovery circuit of claim 8, wherein the feedback loop comprises:
a phase detector to detect a phase difference between the corresponding DLL clock signal for the final buffer and the selected ring oscillator clock signal; and
a charge pump configured to drive the control voltage responsive to the phase difference.

10. The clock data recovery circuit of claim 7, wherein the input clock signal is a source synchronous input clock signal.

11. The clock data recovery circuit of claim 7, wherein the input clock signal is a recovered input clock signal from the received data stream.

12. The clock data recovery circuit of claim 7, wherein the clock data recovery circuit is included within a cellular device.

13. A method of clock data recovery, comprising:
generating a plurality of ring oscillator clock signals in a ring oscillator;
controlling a power supply voltage for the ring oscillator to synchronize the plurality of ring oscillator clock signals with an input clock signal;
selecting from the plurality of ring oscillator clock signals to provide a selected ring oscillator clock signal to a delay-locked loop (DLL);
delaying the selected ring oscillator clock signal through the DLL to generate a plurality of DLL clock signals;
selecting from the plurality of DLL clock signals to provide a selected DLL clock signal; and
sampling a received data stream with the selected DLL clock signal.

14. (canceled)

15. The method of claim 13, wherein the input clock signal is a source-synchronous input clock signal.

16. The method of claim 13, wherein the input clock signal is a recovered input clock signal from the received data stream.

17. A clock data recovery circuit, comprising:
a ring oscillator configured to generate a plurality of ring oscillator clock signals responsive to an input clock signal;
means for synchronizing the plurality of ring oscillator clock signals with the input clock signal;
a delay-locked loop (DLL) configured to delay a selected ring oscillator clock signal from the plurality of ring oscillator clock signals to generate a plurality of DLL clock signals; and
a data sampler configured to sample a received data stream with a selected DLL clock signal from the plurality of DLL clock signals to generate a sampled data stream.

18. The clock data recovery circuit of claim 17, wherein the ring oscillator comprises a plurality of N inverters, each inverter in the plurality of N inverters being configured to generate a corresponding one of the ring oscillator clock signals from the plurality of ring oscillator signals on a one-to-one basis, N being a positive plural integer, and wherein the DLL comprises a plurality of (N−1) buffers, each buffer in the plurality of (N−1) buffers being configured to generate a corresponding one of the DLL clock signals in the plurality of DLL clock signals on a one-to-one basis.

19. The clock data recovery circuit of claim 17, further comprising:
a clock multiplexer configured to select from the plurality of ring oscillator clock signals to provide the selected ring oscillator clock signal.

20. The clock data recovery circuit of claim 18, wherein N equals five.

21. A clock data recovery circuit, comprising:
a phase-locked loop (PLL) including a ring oscillator configured to generate a plurality of ring oscillator clock signals responsive to an input clock signal, the PLL being configured to control a power supply voltage for the ring oscillator to synchronize the plurality of ring oscillator clock signals with the input clock signal;
a first clock multiplexer for selecting from the plurality of ring oscillator clock signals from the ring oscillator to provide a selected ring oscillator clock signal;
a delay-locked loop (DLL);
a second clock multiplexer for selecting from a plurality of DLL clock signals from the DLL to provide a sampling clock signal; and
a data sampler for sampling a received serial data stream with sampling clock signal to provide a series of data samples.

22. The clock data recovery circuit of claim 21, wherein the plurality of inverters in the ring oscillator comprises a plurality of five inverters.

23. The clock data recovery circuit of claim 21, wherein a plurality of delay stages in the DLL comprises a plurality of four delay stages.

24. (canceled)
